(19) United States
(12) Patent Application Publication
(10) Pub. No.: US 2010/0132774 A1
(43) Pub. Date: Jun. 3, 2010

(54) Thin Film Silicon Solar Cell Device With Amorphous Window Layer

(75) Inventor: Peter G. Borden, San Mateo, CA (US)

Correspondence Address: DIEHL SERVILLA LLC, 77 BRANT AVENUE, SUITE 210, CLARK, NJ, 07066, US

(73) Assignee: Applied Materials, Inc., Santa Clara, CA (US)

(21) Appl. No.: 12/332,608

(22) Filed: Dec. 11, 2008

(51) Int. Cl. H01L 31/00; H01L 31/0232

(52) U.S. Cl. 136/255; 438/69; 136/261; 257/E31.127

(57) ABSTRACT

Photovoltaic devices and methods of manufacture are provided. In an embodiment, the devices comprise a micro-crystal silicon cell having an amorphous silicon layer formed on the micro-crystal cell.

### FIELD

Embodiments of the present invention generally relate to photovoltaic (PV) devices and fabrication of photovoltaic devices. In particular, embodiments of the invention relate to amorphous silicon window layer on micro-crystal silicon and creation thereof in photovoltaic devices.

### BACKGROUND

Thin film silicon solar cells for photovoltaic purposes are known. The silicon in a solar device may be classified according to its crystallinity. Commonly used classification of silicon crystallinity include: single-crystalline, polycrystalline, microcrystalline (micro-crystal) and amorphous. An amorphous silicon cell 10 shown in cross-sectional diagram in FIG. 1 may be considered one of the least complex of the silicon solar cell structures. It has a thin (100-200 Å thick) p-type layer 12 and an n-type silicon layer 14 that sandwich a low-doped intrinsic layer 16 on the order of 3000 Å thick. This type of cell, because of defects in the crystal structure, may suffer from a light-induced degradation which is known as the Stabler-Wronski effect, which may result in a loss of 15-20% of its starting efficiency. A similar cell can be made with micro-crystal (μC) silicon. However, in micro-crystal silicon (μC-Si) the low doped intrinsic layer must be much thicker—1.5 to 2 μm—because of the long absorption length in μC silicon. Micro-crystal Si cells do not suffer the light-induced degradation, but take long to form because they are considerably thicker.

The bandgap of a-Si (amorphous silicon) is around 1.8 eV, and the bandgap of μC-Si is around 1.1 eV, so the two can be combined in a well known multi-junction or tandem structure, called a micro-morph, of which a cross-sectional diagram is shown in FIG. 2. In a micro-morph structure 20, the high gap cell, comprising an amporphous silicon p-type layer 22 and an amorphous silicon n-type silicon layer 24 that sandwich a low-doped amorphous silicon intrinsic layer 26, is stacked over the low gap cell, comprising a microcrystalline p-type layer 32 and a microcrystalline n-type silicon layer 34 that sandwich a low-doped microcrystalline intrinsic layer 36, absorbing short wavelength light and transmitting long to the lower cell. This provides a small improvement in efficiency, from around 6-6.5% for the a-Si cell alone to around 8.5% for the combination. These efficiencies are at the module level.

Heterojunctions are also known solar cell structures. The earliest implementation of a heterojunction 40 was applied in the AlGaAs window layer 42 on a GaAs cell, comprising a p-type GaAs layer 44 on an n-type GaAs layer 46, of which a cross-sectional diagram is shown in FIG. 3. A structure of the type shown in FIG. 3 can be made by growing an AlGaAs high bandgap layer a GaAs substrate of opposite conductivity type. Dopants diffuse into the GaAs during growth, forming a p-n junction in the GaAs. The window layer passivates the front surface, providing a significant improvement in efficiency. The AlGaAs layer has minimal absorption, hence the name “window layer.”

Heterojunctions are also used in wafer-based silicon cells, as in the Heterojunction with Intrinsic Thin layer (HIT) cell 50 marketed by Sanyo, a cross-sectional diagram of which is shown in FIG. 4. A thin transparent conductive oxide (TCO) layer 56 is formed over a thin intrinsic (i) a-Si layer 52 formed on an n-type Si substrate 54, forming a heterojunction to collect current. The transparent conductive oxide layer (TCO) 56 is required to provide lateral conductance to grid lines. An n-type a-Si layer 58 may be used on the back to form a back surface passivation.

Proper use of heterojunctions can improve solar cell performance by providing improved carrier confinement at the surface, where much of the carrier recombination occurs. As one skilled in the art will appreciate, no contact layers are shown in FIGS. 1-4.

There is a need for solar cells which provide a higher efficiency. Novel and improved methods and apparatus to produce such devices are also required.

### SUMMARY OF THE INVENTION

One embodiment of the present invention relates to a photovoltaic device, comprising a micro-crystal, thin film silicon solar cell comprising an absorber layer comprising micro-crystal silicon having a bandgap; and a window layer adjacent the absorber layer, the window layer comprising a material with a higher bandgap than the micro-crystal silicon. In one embodiment, the window layer comprises amorphous silicon. In one embodiment, the window layer comprises carbon-doped silicon (Si:C). In one embodiment, the emitter layer has a bandgap of about or greater than 1.3 eV.

In one or more embodiments, the window layer has a thickness less than or equal to about 300 Å, for example, less than or equal to about 100 Å.

In one embodiment, the absorber layer has a first conductivity type of micro-crystal silicon and the window layer has a conductivity type opposite of the first conductivity type. In one or more embodiments, the micro-crystal, thin film silicon solar cell further comprises an emitter layer having a conductivity type opposite the first conductivity type. In one or more embodiments, the micro-crystal, thin film silicon solar cell has an emitter comprising a heterojunction between the absorber layer and the window layer. In one or more embodiments, the window layer comprises an intrinsic sublayer and a doped sublayer.

In one or more embodiments in which the micro-crystal, thin film silicon solar cell comprises an emitter layer having a conductivity type opposite the first conductivity type, the window layer comprises an intrinsic sublayer and a doped sublayer.

In one or more embodiments, in which the micro-crystal, thin film silicon solar cell has an emitter comprises a heterojunction between the absorber layer and the window layer, the window layer comprises an intrinsic sublayer and a doped sublayer.

Another aspect of the invention pertains to a method for manufacturing a photovoltaic cell, comprising forming a transparent conductive oxide layer on a substrate; depositing a doped window layer having a bandgap; depositing a base including a first doped micro-crystal silicon layer having a bandgap lower than the window layer bandgap to provide an emitter; and forming a back contact. In one embodiment, the window layer comprises n-type doped amorphous silicon and the doped micro-crystal silicon layer is p-type doped to provide a heterojunction that provides the emitter. In one embodiment, the window layer comprises p-type doped amorphous silicon and the doped micro-crystal silicon layer is n-type doped to provide a heterojunction that provides the emitter.

The method may further comprise depositing a layer of intrinsic amorphous silicon after depositing the window layer.

In one embodiment, the first doped micro-crystal silicon layer has a first conductivity type and the doped amorphous silicon window layer has a conductivity opposite the first conductivity type, and the method further comprising depositing a second doped micro-crystal silicon layer after depositing the doped window layer, the second doped micro-crystal silicon layer having a conductivity opposite the first conductivity type, and the second doped micro-crystal silicon layer is an emitter layer. In an embodiment, the method may further comprise forming an intrinsic micro-crystal silicon layer between the first and second micro-crystal layers. In one embodiment, the window layer comprises carbon doped silicon.

The foregoing has outlined rather broadly certain features and technical advantages of the present invention. It should be appreciated by those skilled in the art that the specific embodiments disclosed may be readily utilized as a basis for modifying or designing other structures or processes within the scope present invention. It should also be realized by those skilled in the art that such equivalent constructions do not depart from the spirit and scope of the invention as set forth in the appended claims.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1-4 schematically illustrate prior art photovoltaic devices in cross-section;

FIG. 5 schematically illustrates a photovoltaic device in cross-section in accordance with an embodiment of the present invention;

FIG. 6 schematically illustrates a photovoltaic device in cross-section in accordance with another embodiment of the present invention;

FIG. 7 is a flow diagram that schematically illustrates the steps of creating a photovoltaic device in accordance with one or more embodiments of the present invention;

FIG. 8 schematically illustrates the energy band structure of a photovoltaic device in accordance with an aspect of the present invention; and

FIG. 9 schematically illustrates the energy band structure of a photovoltaic device in accordance with another aspect of the present invention.

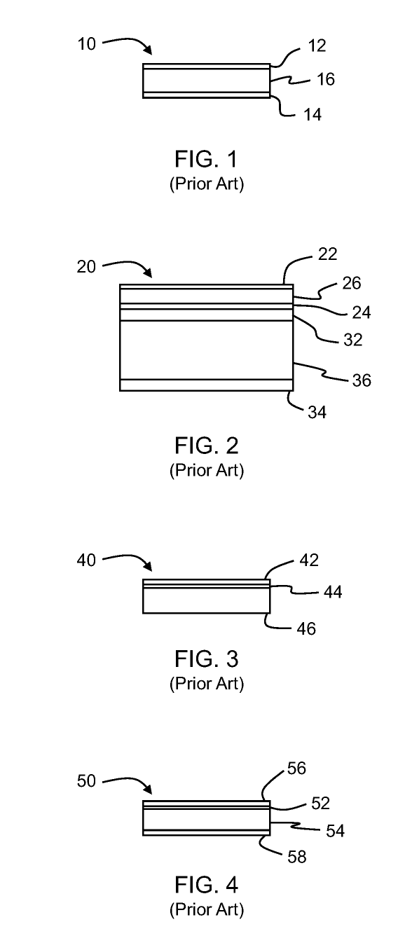

### DETAILED DESCRIPTION

Embodiments of the invention generally provide photovoltaic devices and methods of forming and treating photovoltaic devices. Before describing several exemplary embodiments of the invention, it is to be understood that the invention is not limited to the details of construction or process steps set forth in the following description. The invention is capable of other embodiments and of being practiced or being carried out in various ways.

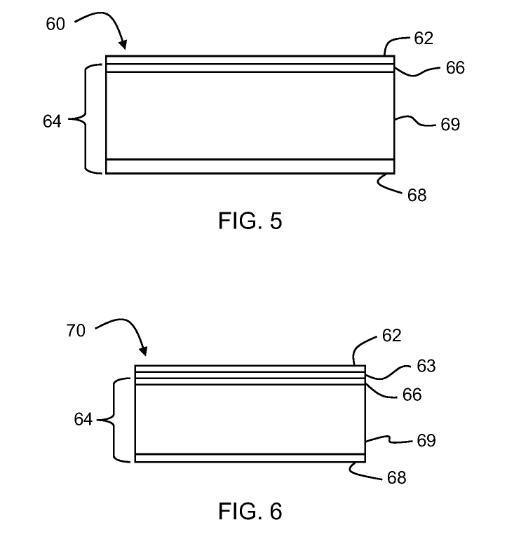

According to one embodiment of the invention, a photovoltaic device 60 comprises a layer of amorphous silicon (“a-Si”) 62 formed over a μC-Si solar cell 64, as shown in FIG. 5. In one embodiment, the a-Si is substantially pure. In other embodiments, the μC-Si 68 is doped to a first conductivity type and the a-Si layer 62 may be doped to the opposite conductivity type of the μC-Si (i.e., the same type as the emitter of the μC-Si cell) as is shown in FIG. 5. As shown in FIG. 5, the μC-Si solar cell 64 comprises an optional first micro-crystal layer 66, a second microcrystal layer 68 and an intrinsic layer 69, which may also be referred to as an intrinsic sublayer, formed between the first and second micro-crystal layers. The optional first micro-crystal layer 66 is doped similarly to the amorphous silicon layer 62. Thus, in the configuration shown, the first micro-crystal layer 66 may be an n-type layer, the second micro-crystal layer 68 may be a p-type layer forming the emitter, and the amorphous silicon layer 62 would be an n-type layer. The a-Si layer 62 and the second micro-crystal layer 68 are, in one or more embodiments, heavily doped. It will be understood that these conductivity types can be reversed, so long as the amorphous silicon layer 62 and the optional first micro-crystal layer are of the same conductivity type.

Alternately, as shown in FIG. 6, device 70 comprises an a-Si layer 62 or may comprise two layers, an a-Si layer 62 and an intrinsic a-Si layer 63. The intrinsic a-Si layer would be adjacent the μC-Si cell 64. The μC-Si cell comprises an optional first micro-crystal layer 66, a second doped micro-crystal layer 68, with an intrinsic micro-crystal layer 69 (which may also be referred to as an intrinsic sublayer) between the two doped micro-crystal layers. As in FIG. 5, the a-Si layer 62 and the second micro-crystal layer 68 are, in one or more embodiments, heavily doped. The first micro-crystal layer 66, although not necessary, can be either an intrinsic micro-crystalline layer or lightly doped. If the first micro-crystal layer 66 is lightly doped, it is of the same doping type as the a-Si layer 62, and in such a case the first microcrystal layer 66 may be referred to as a lightly doped sublayer. As used in this specification and the appended claims, “lightly doped” means doped up to about 10¹⁷ atoms/cm³, generally in the range of about 10¹⁶ atoms/cm³ to 10¹⁷ atoms/cm³. “Heavily doped” material contain greater than about 10¹⁸ atoms/cm³, generally in the range of about 10¹⁸ atoms/cm³ to 10²⁰ atoms/cm³. Regular doping levels fall approximately in the range between the lightly doped and heavily doped ranges.

A variety of doping schemes can be used according to various embodiments. For example, if the base or back of the μC cell is p-type, the bulk can be low doped p-type or intrinsic. An n-type emitter can be formed in the μC cell, followed by deposition of i-type and n-type a-Si or, alternately, n-type alone. According to one or more embodiments, the a-Si window layer is thin, on the order of about 200 Å or less, and in specific embodiments, about 100 Å or less, which prevents excess absorption in that layer.

In another embodiment, a doped amorphous silicon layer can be formed over intrinsic (undoped) amorphous silicon (for example, about 50 Å thick) over undoped or lightly n-type doped micro-crystal silicon over a back layer of doped n-type micro-crystal silicon. In such embodiments, the amorphous silicon layer would have the opposite conductivity type of the layer which it overlies. Accordingly, in the immediate example provided above with an n-type doped micro-crystal silicon, the amorphous silicon layer would be p-type. An exemplary thickness for the amorphous silicon layer of such embodiments is in the range of about 50 to 100 Å. Note that this embodiment does not have an emitter in the μ-crystal silicon layer.

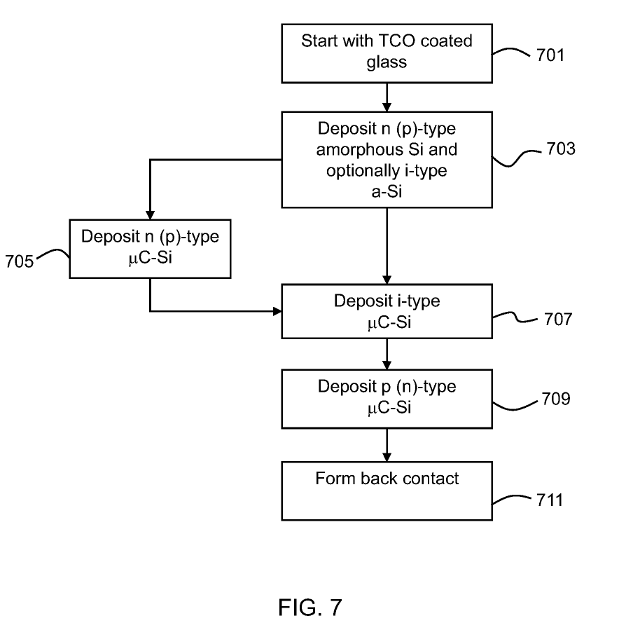

The structures as shown in FIGS. 5 and 6 can be formed using the process flow of steps as shown in FIG. 7. According to one or more embodiments, the process steps include the doping of the micro-crystal silicon which may be performed by diffusion suitable process, for example deposition. In the embodiment shown in FIG. 7, the process starts at step 701 with a glass substrate and includes a TCO layer. Typically either the glass or the TCO is textured to enhance light trapping. In step 703 an a-Si layer is deposited, which includes a doped amorphous silicon layer (which, as shown, may be n-type or p-type), and an optional i-type amorphous silicon layer. The μC cell is then formed. It may be a complete cell formed in optional step 705 with an emitter of the same doping type as the doped a-Si, a lightly doped base, and a back high-doped contact layer of the opposite type of the emitter. Alternately as shown as step 707, the μC cell may not have an emitter, using the heterojunction formed in Step 709 in which p (n)-type μ crystal silicon layer is deposited to form the emitter. In step 711, a back contact layer is formed.

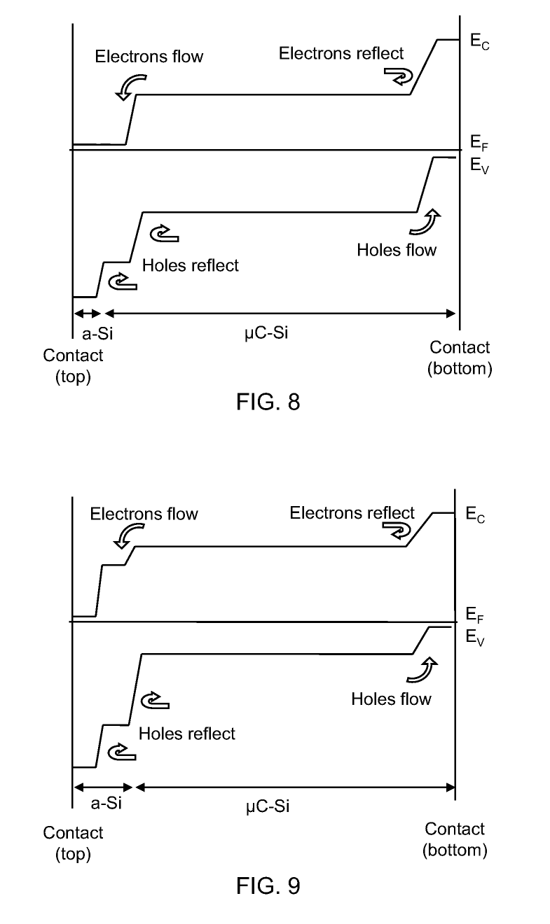

FIGS. 8 and 9 show the band structures of embodiments of cells with a doped a-Si and doped/i-type a-Si window layer respectively. In the Figures, E_{C} is the conduction band energy, E_{F} is the Fermi level and E_{V} is the valence band energy level. The left side of the diagrams in FIGS. 8 and 9 represent the top contact of the cell and the right side represents the bottom contact. The window layer is seen to form a high barrier to minority carriers (e.g. holes in the top layer), providing confinement and, therefore, reduced recombination. This will have the effect of increasing the cell current and voltage. A difference between the embodiments illustrated by FIGS. 8 and 9 is the use of an intrinsic window layer in the latter case. FIG. 8 shows a cell with an n-type emitter in the μC silicon. Note that the conduction band is close to the Fermi energy and the bandgap is the same as in the bulk. An n-type a-Si layer is placed on top, which has a higher bandgap value. In FIG. 9, the substrate is lightly doped p-type and the intrinsic layer has a larger bandgap, because it is made out of a-Si.

In an alternative embodiment, of applying a doped a-Si window layer could be used to also increase the efficiency of an amorphous silicon solar cell by depositing an emitter with a higher bandgap than the base to form a heterojunction.

It will be appreciated that according to alternative embodiments, other materials than those discussed above may be used for the emitter and window layers described, so long as the bandgap and doping relationships are as described above. For example, in one embodiment, carbon doped silicon (Si:C) is used instead of amorphous silicon as a window layer.

In one embodiment of the present invention, amorphous silicon is used as a window layer in a silicon photovoltaic device. The embodiment has several benefits over an amorphous or micro-morph cell. These benefits include: (1) there is no current matching requirement; (2) improved short-circuit current density J_{SC} and open-circuit voltage V_{OC} through front surface passivation by the window layer; (3) Stabler-Wronski effect in the cell is reduced.

A layer may be called substantially of a certain material of a certain crystalline structure. This is intended to mean that doping material will not change such a designation, unless specifically identified as such. This means, that for instance, an intrinsic layer and a doped layer of micro-crystal silicon may herein still be considered a layer that both are substantially made of micro-crystalline silicon.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments. The order of description of the above method should not be considered limiting, and methods may use the described operations out of order or with omissions or additions.

It is to be understood that the above description is intended to be illustrative, and not restrictive. Many other embodiments will be apparent to those of ordinary skill in the art upon reviewing the above description. The scope of the invention should, therefore, be determined with reference to the appended claims, along with the full scope of equivalents to which such claims are entitled.

1. A photovoltaic device, comprising:
a micro-crystal, thin film silicon solar cell comprising an absorber layer comprising micro-crystal silicon having a bandgap; and
a window layer adjacent the absorber layer, the window layer comprising a material with a higher bandgap than the micro-crystal silicon.

2. The photovoltaic device of claim 1, wherein the window layer comprises amorphous silicon.

3. The photovoltaic device of claim 1, wherein the window layer comprises carbon doped silicon.

4. The photovoltaic device of claim 1, wherein the window layer has a thickness less than or equal to about 300 Å.

5. The photovoltaic device of claim 1, wherein the window layer has a thickness of less than or equal to about 100 Å.

6. The photovoltaic device of claim 2, wherein the absorber layer has a first conductivity type of micro-crystal silicon and the window layer has a conductivity type opposite of the first conductivity type.

7. The photovoltaic device of claim 6, wherein the micro-crystal, thin film silicon solar cell further comprises an emitter layer having a conductivity type opposite the first conductivity type.

8. The photovoltaic device of claim 6, wherein the micro-crystal, thin film silicon solar cell has an emitter comprising a heterojunction between the absorber layer and the window layer.

9. The photovoltaic cell of claim 6, wherein the window layer comprises an intrinsic sublayer and a doped sublayer.

10. The photovoltaic cell of claim 7, wherein the window layer comprises an intrinsic sublayer and a doped sublayer.

11. The photovoltaic cell of claim 8, wherein the window layer comprises an intrinsic sublayer and a doped sublayer.

12. The photovoltaic cell of claim 1, wherein an emitter layer has a bandgap of about or greater than 1.3 eV.

13. A method for manufacturing a photovoltaic cell, comprising:
forming a transparent conductive oxide layer on a substrate;
depositing a doped window layer having a bandgap;
depositing a base including a first doped micro-crystal silicon layer having a bandgap lower than the window layer bandgap to provide an emitter; and
forming a back contact.

14. The method of claim 13, wherein the window layer comprises n-type doped amorphous silicon and the doped micro-crystal silicon layer is p-type doped to provide a heterojunction that provides the emitter.

15. The method of claim 13, wherein the window layer comprises p-type doped amorphous silicon and the doped micro-crystal silicon layer is n-type doped to provide a heterojunction that provides the emitter.

16. The method of claim 13, further comprising depositing a layer of intrinsic amorphous silicon after depositing the window layer.

17. The method of claim 13, wherein the first doped micro-crystal silicon layer has a first conductivity type and the doped amorphous silicon window layer has a conductivity opposite the first conductivity type, and the method further comprising depositing a second doped micro-crystal silicon layer after depositing the doped window layer, the second doped micro-crystal silicon layer having a conductivity opposite the first conductivity type, and the second doped micro-crystal silicon layer is an emitter layer.

18. The method of claim 17, further comprising forming an intrinsic micro-crystal silicon layer between the first and second micro-crystal layers.

19. The method of claim 18, wherein the doped amorphous layer has a thickness of less than or equal to about 300 Å.

20. The method of claim 13, wherein the window layer comprises carbon doped silicon.
